(19) United States
(12) Patent Application Publication
(10) Pub. No.: US 2008/0094107 A1
(43) Pub. Date: Apr. 24, 2008

(54) Signal magnitude comparison apparatus and methods

(75) Inventors: Stephane Dallaire, Gatineau (CA); Brian Glenn Wall, Stittsville (CA); Shawn Lawrence Scouten, Ottawa (CA); Colin Harvey Cramm, Ottawa (CA); Kenji Suzuki, Kanata (CA); Stephen Alie, Ottawa (CA); Andrew Deczky, Ottawa (CA)

Correspondence Address: SMART & BIGGAR;P.O. BOX 2999, STATION D, 900-55 METCALFE STREET, OTTAWA, ON, K1P5Y6, US

(73) Assignee: CORTINA SYSTEMS, INC.

(21) Appl. No.: 11/583,785

(22) Filed: Oct. 20, 2006

(51) Int. Cl. H03K 5/22

(52) U.S. Cl. 327/63

(57) ABSTRACT

Signal magnitude comparison apparatus and methods are disclosed. A first input circuit receives a differential input signal and provides a first output signal based on a magnitude of the differential input signal. A second input circuit is operatively coupled to the first input circuit and is operable to receive a second input signal, which may also be a differential signal, and to provide a second output signal based on a magnitude of the second input signal. The operative coupling between the first and second input circuits results in the first output signal and the second output signal forming a differential output signal that is indicative of a difference between the magnitude of the first differential input signal and the magnitude of the second input signal.

### FIELD OF THE INVENTION

This invention relates generally to electronic signal processing and, in particular, to comparing signal magnitudes.

### BACKGROUND

Traditional approaches and architectures for adaptive equalization and other applications in which signal comparisons are performed for binary and other multi-level signals may require multiple comparator circuits. In systems that use +1/−1 binary signals, for example, two comparators might be required, including one comparator for the +1 positive level and another comparator for the −1 negative level.

FIG. 1A illustrates an adaptive equalization system in which this type of architecture is used. The system shown in FIG. 1A includes an equalizer 20, which could include either or both of a feedforward equalizer (FFE) and a decision feedback equalizer (DFE), comparators 22A, 22B, decision circuits 24A, 24B, 24C, and an adaptation module 26. The two comparators 22A, 22B respectively compare an output from the equalizer 20 to a positive reference, shown as a target equalized positive signal level, and to a negative reference, shown as a target equalized negative signal level, and generate error signals errh(t) and errl(t). The output of the equalizer is also passed through decision circuit 24A to produce the recovered bit stream z(t). Each of errh(t) and errl(t) is also processed with a respective decision circuit 24B,24C to produce ERRH(t) and ERRL(t). A selector such as a switch or a multiplexer (not shown) selects ERRH(t) as an error signal for input to the adaptation module 26 when a bit in the bit stream z(t) that is recovered from an equalized bit stream y(t) is positive (+1), and selects ERRL(t) as the error signal when a recovered bit is negative (−1). The recovered bit, the selected error signal, and an adaptation algorithm are used by the adaptation module 26 to determine coefficients of the equalizer 20.

Another adaptive equalization system is shown in FIG. 1B, and includes an equalizer 28, a delay element 30, a single comparator 32, decision circuits 34A, 34B, and an adaptation module 36. In this system, decision circuit 34A again is used produce the recovered bit stream z(t) which has been limited to arbitrary +1/−1 levels and retimed. The single comparator 32 compares the recovered bit stream z(t) to a version of the equalized signal y(t) that is output from the equalizer 28 and delayed by the delay element 30. The purpose of the delay element 30 is to properly align the two bit streams y(t) and z(t) in time. Although this architecture requires only one comparator 32, it can be challenging to implement due to the difficulty of aligning the two comparator input signals y(t) and z(t) in time, especially at data rates in excess of 1 Gb/s.

Signal-to-Noise Ratio (SNR) and Bit Error Rate (BER) monitoring represent additional applications of signal comparison techniques. Currently available SNR/BER monitors for binary or other multi-level signals, such as those disclosed in U.S. Pat. Nos. 3,721,959 and 4,823,360, similarly use multiple comparators. For example, one comparator might compare an eye pattern to a “high” reference, with another comparator comparing the eye pattern to a “low” reference in a system that uses binary signals.

Other previously proposed SNR/BER monitor schemes require higher-level processing and/or coding/decoding of received data. Schemes requiring high-level processing include parity checking and Cyclic Redundancy Check (CRC). Duo-binary and 8B/10B schemes, for example, require coding/decoding.

Thus, there remains a need for improved signal comparison techniques.

### SUMMARY OF THE INVENTION

Embodiments of the invention may be used, for example, to provide simple and versatile SNR/BER monitoring. A monitoring function can be implemented at a low-level, independent of signal coding and communication protocols.

Some embodiments of the invention may also provide improved performance and/or reduced power consumption for signal processing systems.

An apparatus according to an aspect of the invention includes a first input circuit operable to receive a differential input signal and to provide a first output signal based on a magnitude of the differential input signal, and a second input circuit operatively coupled to the first input circuit and operable to receive a second input signal and to provide a second output signal based on a magnitude of the second input signal. The first output signal and the second output signal comprise a differential output signal that is indicative of a difference between the magnitude of the first differential input signal and the magnitude of the second input signal.

The first input circuit may include a pair of controllable switch elements, each controllable switch element being operatively coupled between supply rails and operable to receive as a control input a respective one of a pair of input signals comprising the first differential input signal, and to provide, under control of its control input, a respective connection between the supply rails.

The first input circuit may also include a load operatively coupled between the pair of controllable switch elements and one of the supply rails.

In some embodiments, the apparatus includes a connection circuit operatively coupling the first input circuit to the second input circuit. The connection circuit may include a current source operatively coupling both the first input circuit and the second input circuit to one of the supply rails.

The second input circuit may include a controllable switch circuit operatively coupled between supply rails and operable to receive as a control input the second input signal, and to provide, under control of the second input signal, a connection between the supply rails.

Where the second input signal is a differential input signal, the controllable switch circuit may include a pair of controllable switch elements, each controllable switch element being operatively coupled to the supply rails and operable to receive as a control input a respective one of a pair of input signals comprising the second differential input signal, and to provide, under control of its control input, a respective connection between the supply rails.

The second input circuit may also include a load operatively coupled between the controllable switch circuit and one of the supply rails.

A connection circuit is provided in some embodiments to operatively couple the first input circuit to the second input circuit. The connection circuit may include a current source operatively coupling both the first input circuit and the second input circuit to one of the supply rails.

In some embodiments, the first input circuit and the second input circuit include controllable switch elements.

Such an apparatus may be implemented, for example, in an error comparator that is operatively coupled to the equalizer of a signal equalization system. In this case, the apparatus may be operable to receive an equalized signal from the equalizer and a reference signal as the first differential input signal and the second input signal, respectively. The signal equalization system may also include respective decision circuits operatively coupled to the equalizer and to the error comparator, and an adaptation module that is operatively coupled to the decision circuits and to the equalizer and is operable to determine the equalizer coefficients based on outputs of the decision circuits.

In some embodiments, the equalization system also includes an offset element operatively coupled to the error comparator and operable to adjust the reference signal by an offset amount and to provide the adjusted reference signal to the error comparator as the second input signal, and an accumulator operatively coupled to the error comparator decision circuit and operable to accumulate a number of times at which the differential output signal indicates that a magnitude of the equalized signal is above a magnitude of the adjusted reference signal when the reference signal is increased by the offset amount, and to accumulate a number of times at which the differential output signal indicates that a magnitude of the equalized signal is below a magnitude of the adjusted reference signal when the reference signal is decreased by the offset amount.

Another possible implementation of such an apparatus is in a signal monitor that also includes an offset element operatively coupled to the apparatus and operable to adjust a reference signal by an offset amount and to provide the adjusted reference signal to the error comparator as the second input signal, a decision circuit operatively coupled to the apparatus to receive the differential output signal, and an accumulator operatively coupled to the apparatus and operable to accumulate a number of times at which the differential output signal indicates that a magnitude of the first differential input signal is above a magnitude of the adjusted reference signal when the reference signal is increased by the offset amount, and to accumulate a number of times at which the differential output signal indicates that a magnitude of the first differential input signal is below a magnitude of the adjusted reference signal when the reference signal is decreased by the offset amount.

A method according to another aspect of the invention involves receiving a first differential input signal and a second input signal, converting the first differential input signal and the second input signal into respective output signals based on magnitudes of the first differential input signal and the second input signal, and providing a differential output signal comprising the respective output signals, the differential output signal being indicative of a difference between the magnitude of the first differential input signal and the magnitude of the second input signal.

A further aspect of the invention provides an apparatus that includes a pair of input circuits operable to respectively receive a first differential input signal and a second input signal, and to provide respective output signals based on a magnitude of the first differential input signal and a magnitude of the second input signal, and a connection circuit operatively coupling the pair of input circuits together, such that the respective output signals comprise a differential output signal that is indicative of a difference between the magnitude of the first differential input signal and the magnitude of the second input signal.

Other aspects and features of embodiments of the present invention will become apparent to those ordinarily skilled in the art upon review of the following description.

### BRIEF DESCRIPTION OF THE DRAWINGS

Examples of embodiments of the invention will now be described in greater detail with reference to the accompanying drawings in which:

FIG. 1A is a block diagram of a conventional adaptive equalization system;

FIG. 1B is a block diagram of another conventional adaptive equalization system;

FIG. 2 is a block diagram of a signal comparison apparatus according to an embodiment of the invention;

FIG. 3 is a block diagram of a signal comparison apparatus according to another embodiment of the invention;

FIG. 4 is a block diagram showing a signal comparison apparatus of a further embodiment of the invention;

FIG. 5 is a block diagram of a signal comparison apparatus of yet another embodiment of the invention;

FIG. 6 is a block diagram of an adaptive equalization system incorporating a signal comparison apparatus according to an embodiment of the invention;

FIG. 7 is a plot of an eye pattern and reference levels for a binary signal;

FIG. 8 is a plot of magnitudes of the eye pattern and reference levels shown in FIG. 7;

FIG. 9 is a block diagram of a signal monitor that incorporates a signal comparison apparatus of an embodiment of the invention; and

FIG. 10 is a block diagram of an optical module incorporating a signal comparison apparatus according to an embodiment of the invention.

### DETAILED DESCRIPTION OF PREFERRED EMBODIMENTS

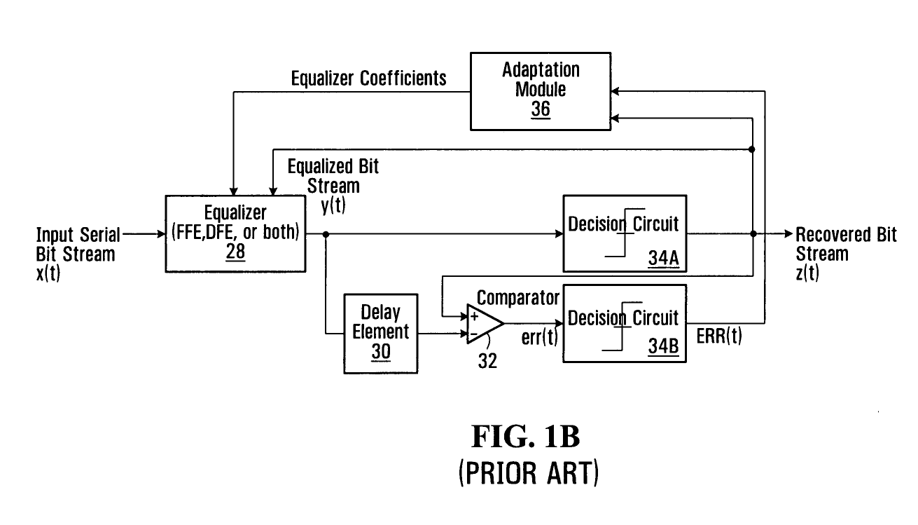

FIG. 2 is a block diagram of a signal comparison apparatus according to an embodiment of the invention. The embodiment shown in FIG. 2 represents a Complementary Metal Oxide Semiconductor (CMOS) implementation. Other implementations may also be or become apparent to those skilled in the art. It should therefore be appreciated that the system of FIG. 2, as well as the contents of the other drawings, are intended solely for illustrative purposes, and that the present invention is in no way limited to the particular example embodiments explicitly shown in the drawings and described herein.

The apparatus shown in FIG. 2 includes Metal Oxide Semiconductor Field Effect Transistors (MOSFETS) M1, M2, whose gate terminals receive a differential input signal, vip-vin. The gate terminals of another pair of transistors M3, M4 receive a differential reference signal, vrefp-vrefn. The transistors M1, M2 have their source terminals connected together and their drain terminals connected together. The transistors M3, M4 are connected the same way as the transistors M1, M2, with their source terminals connected together and their drain terminals connected together. These and other connections shown in FIG. 2 might be direct connections between component leads, or indirect, through conductors such as jumpers or traces on an integrated circuit or on a printed circuit board for instance.

The source terminals of the transistors M1, M2, M3, M4 are all connected together and to the drain terminal of a transistor M5, which is connected to a negative supply voltage and operates as a current source. The bias current through the transistor M5, Ids_m5, is set by a control voltage, vbias. The drain terminals of M1, M2 are connected to a positive supply voltage through a resistor R1, and the drain terminals of the transistors M3, M4 are similarly connected to the positive supply voltage through a resistor R2. A differential output voltage signal, vop-von, is taken at the drain terminals of transistor pair M1, M2 and the transistor pair M3, M4, respectively.

Each paired transistor configuration of M1, M2 and M3, M4 behaves effectively like a rectifier or a magnitude converter. That is, the total drain current flowing across the transistor pair M1, M2, denoted Ids_m1+Ids_m2, is proportional to the peak or maximum voltage of the two input voltages, max(vip,vin). Moreover, in the case where vip and vin represent a differential voltage with a given common mode voltage (vip+vin)/2, the total drain current flowing across the transistor pair M1, M2 is proportional to the absolute value of the differential voltage, abs(vip-vin). For the transistor pair M3, M4, the total drain current Ids_m3+Ids_m4 is similarly proportional to the peak or maximum voltage, of the two input voltages max(vrefp,vrefn), or to the absolute value, abs(vrefp-vrefn).

In the context of the present disclosure, absolute values and peak/maximum values may be considered examples of signal magnitudes. References to magnitudes in the present specification, including the claims, should be interpreted accordingly, to encompass absolute values and/or peak/maximum values.

Assuming appropriate selection of R1 and R2 (usually equal, assuming equal positive supply rail voltages in the embodiment shown in FIG. 2), provided vip-vin and vrefp-vrefn have substantially the same common-mode voltage, i.e., (vip+vin)/2≈(vrefp+vrefn)/2, the differential output voltage, vop-von, is proportional to the difference between the magnitude of the differential input voltage, illustratively abs(vip-vin), and the magnitude of the differential reference voltage, illustratively abs(vrefp-vrefn).

The apparatus of FIG. 2 thus generates a differential output signal, vop-von, having a magnitude that is indicative of the difference between the magnitude of a differential input voltage, vip-vin, and the magnitude of an adjustable differential reference voltage, vrefp-vrefn.

As noted above, the present invention is in no way limited to the specific apparatus shown in FIG. 2. For example, a cascode current source or a simple resistor could be used instead of the transistor M5 as a current source. Active loads could also be used instead of the passive resistor loads R1 and R2.

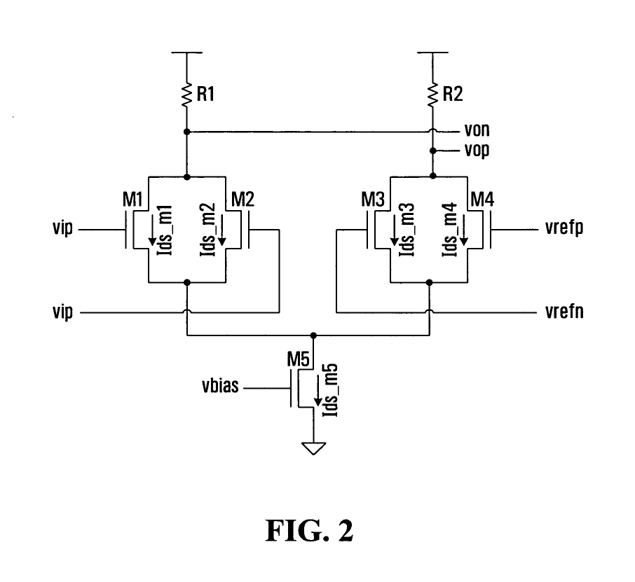

Different types of transistors could similarly be used instead of the MOSFETs M1, M2, M3, M4. FIG. 3 is a block diagram of a signal comparison apparatus according to another embodiment of the invention, which is implemented using Bipolar Junction Transistors (BJTs) Q1, Q2, Q3, Q4, Q5. The same or different values of bias voltage, resistors R1, R2, R3, and/or supply voltages may be used in CMOS and bipolar implementations. A bipolar transistor implementation otherwise operates in substantially the same way as the CMOS implementation described above.

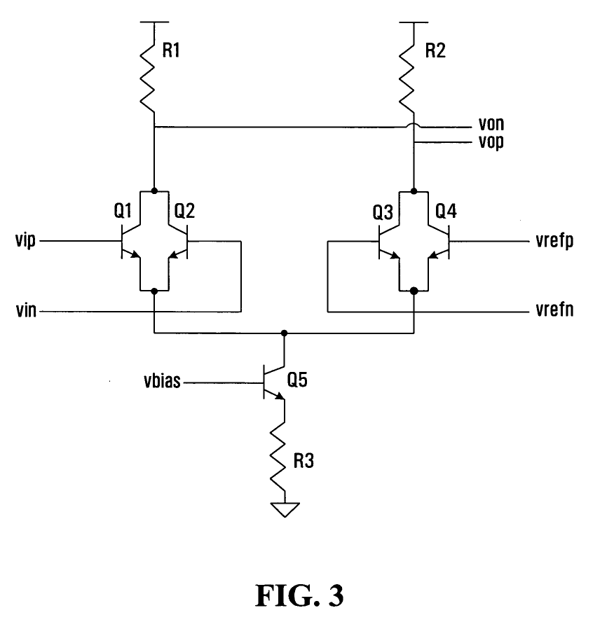

FIG. 4 is a block diagram showing a signal comparison apparatus of a further embodiment of the invention, and illustrates another variation of the comparison apparatus of FIG. 2. In FIG. 4, the adjustable reference voltage vref is single-ended. In this case, as shown, the gate terminal of only one reference transistor M4 receives the reference signal. In one possible implementation, the same circuit is provided for single-ended or differential reference signals, with only one gate terminal (vrefp, FIG. 2) actually being connected to receive a reference signal when a single-ended reference signal is used. Thus, the transistor M3 (FIG. 2) might also be present in an implementation for a single-ended reference signal, but its gate terminal is not connected to receive a reference signal. The gate terminal of the unused transistor, M3 in this example, is preferably biased such that M3 is turned off. This may be accomplished by connecting the gate terminal of M3 to the negative supply, for instance.

As noted above with reference to FIG. 2, the differential output voltage vop-von is proportional to the difference between abs(vip-vin) and abs(vrefp-vrefn) where vip-vin and vrefp-vrefn have substantially the same common-mode voltage. In the case of a single-ended reference signal, max(vip-vin) is compared to the single-ended reference signal. However, with an appropriate choice of common-mode voltage, (vip+vin)/2, and a single-ended reference, vref, it is possible to accomplish the same function of generating a differential output signal that is proportional to the difference between abs(vip-vin) and vref. For example, in one embodiment, a 1.2 Volt positive supply, a 0.8 Volt common-mode voltage, and a 1.0 Volt single-ended reference are used. Note that this is equivalent to comparing vip-vin to a 0.4 differential reference, i.e. vrefp-vrefn. It should be appreciated that this combination of a common-mode voltage and a reference signal is intended solely for illustrative purposes, and that this combination or other combinations may be used in different embodiments.

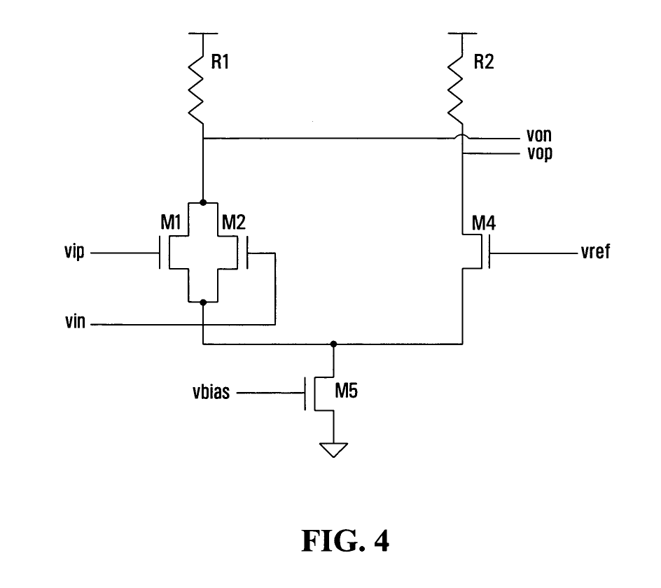

A bipolar transistor implementation for a single-ended reference signal is shown in the block diagram of FIG. 5 as another embodiment of the invention.

Other variations of the specific circuits shown in FIGS. 2 to 5 may be or become apparent to those skilled in the art. Implementations using MEtal Semiconductor Field Effect Transistors (MESFETs), PMOS transistors, PNP transistors, further types of components, and combinations of different component types, are contemplated.

The circuits shown in FIGS. 2 to 5 represent possible implementations of a signal comparison apparatus according to embodiments of the invention. Each apparatus includes a first input circuit that receives a differential input signal and provides an output signal based on the magnitude of the differential input signal. A second input circuit is operatively coupled to the first input circuit, but receives a second input signal and provides a second output signal based on the magnitude of the second input signal. In the embodiments shown in FIGS. 2 to 5, the input circuits are controllable switch circuits that include controllable switches in the form of transistors.

Since the first and second circuits are operatively coupled together in a differential amplifier structure, a differential output signal that includes the first and second output signals is indicative of a difference between the magnitudes of the input signals. This operative coupling, which may include a current source in the illustrated embodiments, thus effectively regulates the operation of the input circuits.

The signal comparison techniques proposed herein may be used, for example, in an error comparator of an adaptive equalizer or in an SNR/BER monitor. Although these two applications are considered in detail below, it should be appreciated that these techniques may also be used for other purposes, which may be or become apparent to those skilled in the art.

### Adaptive Equalization

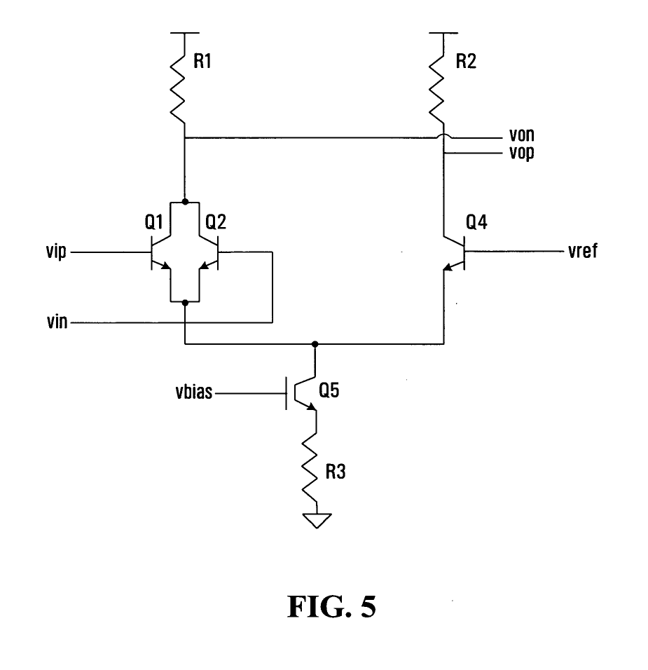

FIG. 6 is a block diagram of an adaptive equalization system incorporating a signal comparison apparatus according to an embodiment of the invention. As shown, the system includes an equalizer 40, a decision circuit 44A and an error comparator 42 operatively coupled to the equalizer, a decision circuit 44B operatively coupled to the error comparator, and an adaptation module 46 operatively coupled to the decision circuits and to the equalizer.

Those skilled in the art will be familiar with various forms of equalizers, decision circuits, and adaptation algorithms that may be used in the adaptation module 46. In general, the equalizer 40 receives and equalizes a signal in accordance with equalization coefficients. The error comparator 42 receives the equalized signal from the equalizer 40 as a differential input signal, vip-vin, and a differential reference signal, vrefp-vrefn. Outputs from the decision circuits 44A, 44B are used by the adaptation module 46 to determine the equalizer coefficients based on outputs of the decision circuits.

Adaptive equalizers as shown in FIG. 6 are typically used in electronic and optical data transmission systems to adaptively compensate for Inter-Symbol Interference (ISI) and/or noise created by effects such as distortion, dispersion, bandwidth limitation, etc., in a communication channel through which binary or other multi-level data is transmitted. An adaptation algorithm applied by the adaptation module 46 adapts equalizer coefficients used by the equalizer 40 in such a way as to minimize noise and ISI. This is often accomplished through the use of an error signal, which is a continuous or a discrete time measure of the difference between the equalizer output and the target signal amplitude or eye opening.

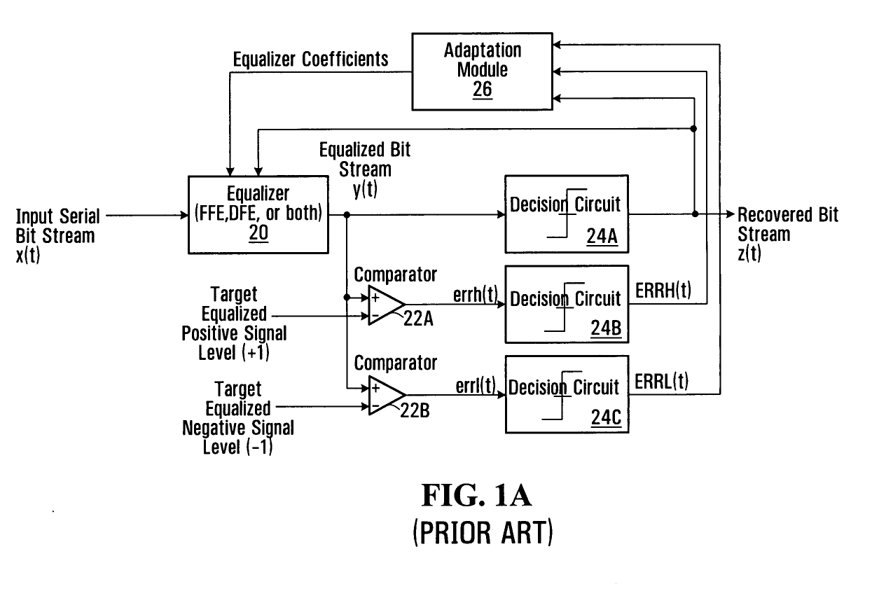

As noted above with reference to FIG. 1A, generation of an error signal in conventional adaptive equalizers for binary or other multi-level bit streams may require multiple comparators. In the system of FIG. 6, a differential reference signal that corresponds to the target signal levels desired at the output of the equalizer 40, illustratively the target levels for +1 and −1 binary levels, is provided to a single error comparator 42. The output of the error comparator 42, e(t), is proportional to the difference between the absolute value or magnitude of the differential equalized signal, abs(y(t)) and the absolute value or magnitude of the differential reference signal, abs(vref). This output is limited to arbitrary +1/−1 levels in this example and retimed by the decision circuit 44B, and is sent as a signal E(t) to the adaptation module 46 along with the decision output z(t), which has also been limited and retimed by the decision circuit 44A.

Knowing the limited and retimed version E(t) of the error comparator output, e(t), and the decision output, z(t), an error signal, ERR(t), can be derived at the adaptation module 46 as ERR(t)=z(t)* E(t), where both E(t) and z(t)=+1 or −1.

In other embodiments, different error signal generation algorithms may be used.

Where the reference for the negative level of a binary differential signal is the inverse of that for the positive level, such that vref(−1)=−vref(+1), the techniques disclosed herein may allow only one comparator to be used in an adaptive equalizer as an error comparator. The error comparator then compares the absolute value or magnitude of an equalized signal to the reference magnitude. This simplifies the implementation and reduces power consumption of an equalizer system, which can be particularly important for high-speed serial communications at data rates greater than 1 Gb/s, for instance.

### SNR/BER Monitor

In electronic and optical data transmission, the quality or reliability of a transmission system may be expressed in terms of SNR and/or BER, which can be shown to be related to SNR. SNR/BER monitor circuits are typically used at the receiving end of a transmission system to continuously or periodically determine the quality of a communication link. Ideally, this function should be performed without disrupting normal data transmission. The signal comparison techniques disclosed herein can be used to implement a circuit or system for monitoring SNR/BER, in a receiver that might, but need not necessarily, also support adaptive equalization capabilities.

An SNR/BER monitor can be used, for example, to monitor the quality of a communication channel or to determine if an equalizer has successfully compensated for channel ISI and noise. In one possible implementation, once the equalizer 40 (FIG. 6) has adapted for a period of time, the adaptation module 46 can be frozen or stopped, and the error comparator 42 can then be used to determine the SNR/BER at the equalizer output.

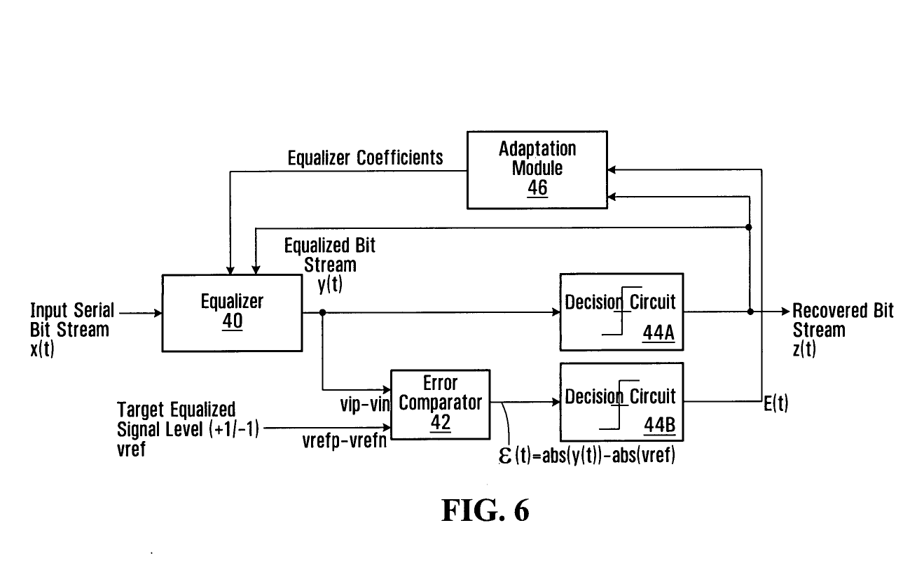

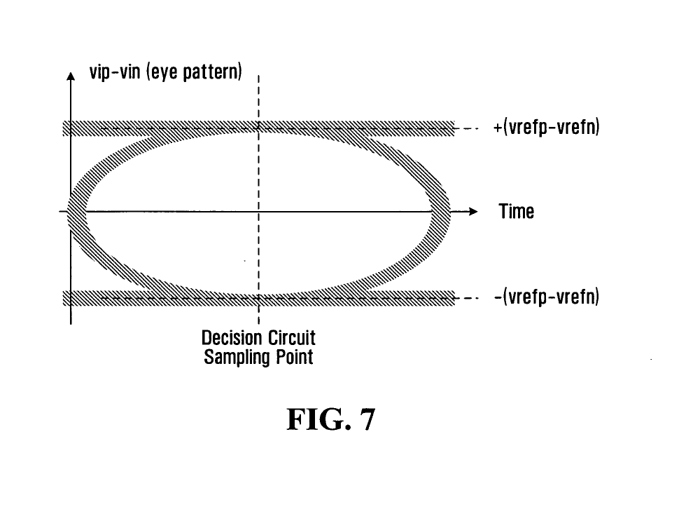

FIG. 7 is a plot of an eye pattern and reference levels for a binary signal, and FIG. 8 is a plot of magnitudes of the eye pattern and reference levels shown in FIG. 7. These plots will be useful in illustrating SNR/BER monitoring aspects of embodiments of the invention.

As shown in FIG. 8, the differential reference input to a signal comparator, vrefp-vrefn, can be successively offset by a pre-determined amount, voffset, on both sides of the normal reference value setting, which may have been used during adaptive equalization. For a positive offset setting, a determination is made as to the number of occurrences, at the decision circuit sampling point, that an input signal, illustratively an equalized signal, is above the offset reference signal during a pre-defined time period. The number of occurrences, at the decision circuit sampling point, that the equalized signal is below the offset comparator reference is similarly determined for the negative offset setting over a time period of equal length.

Assuming that the input signal at the decision circuit sampling point follows a Gaussian distribution centered at the comparator reference voltage, the determined numbers represent the number of occurrences on the “tails” of the Gaussian distribution, as shown in FIG. 8. Knowing the offset applied to the reference, the tail “integration” time period, and the total number of occurrences on the tails of the Gaussian distribution, it is possible to infer the SNR/BER of the input signal. If the objective of monitoring is only to ensure that the SNR is above an acceptable threshold or that the BER is below an acceptable threshold, then the total number of occurrences on the tails of the Gaussian distribution can simply be compared to a threshold.

A more detailed analysis of SNR/BER monitoring is presented below. For simplicity, all of the signals defined and discussed below are assumed single-ended. However, the same conclusions also hold for differential signals.

Consider now an example in which vᵢ is the signal for which SNR is to be estimated, and that the magnitude of vᵢ at the timing recovery sampling point, |vᵢ|ₛ, follows a Gaussian distribution given by:

$$g ( {\vert {v}_{i} \vert}_{s} ) = \frac{1}{σ \sqrt{2 π}} {e}^{- \frac{{( {\vert {v}_{i} \vert}_{s} - \vert {v}_{ref} \vert - μ )}^{2}}{2 {σ}^{2}}} \qquad ( 1 )$$

where

σ the standard deviation of the distribution, which is the unknown quantity;

|v_{ref}| is the magnitude of the reference signal applied to the comparator, which is the target signal amplitude; and

μ represents any residual offset due to non-idealities such as non-linearities, quantization errors, etc.

Let vₒₛ be the output of the comparator at the sampling point. Assuming that the comparator is linear, its output is given by:

vₒₛ=A(|vᵢ|ₛ−|v_{ref}|) (2)

where

A is the gain of the comparator.

Assuming that A is unity to simplify the analysis, the statistical distribution of vₒₛ is given by:

$$g ( {v}_{os} ) = \frac{1}{σ \sqrt{2 π}} {e}^{- \frac{{( {v}_{os} - μ )}^{2}}{2 {σ}^{2}}} . \qquad ( 3 )$$

When a positive offset, v_{offset}, is applied to the comparator reference, v_{ref}, the comparator output becomes:

v_{os,plus}=|vᵢ|ₛ−|v_{ref}+v_{offset}|=|vᵢ|ₛ−v_{ref}−v_{offset} (4)

if v_{ref}+v_{offset}≧0.

The statistical distribution then becomes:

$$g ( {v}_{os , plus} ) = \frac{1}{σ \sqrt{2 π}} {e}^{\frac{{( {v}_{os , plus} + {v}_{offset} - μ )}^{2}}{2 {σ}^{2}}} . \qquad ( 5 )$$

Let sgn(v_{os,plus})=1 when v_{os,plus}≧0 and let sgn(v_{os,plus})=−1 when v_{os,plus}<0. For n samples, we have:

$$\begin{matrix}{Total}_{1 , plus} = {\sum }_{i = 1}^{n} \frac{( sgn ( {v}_{os , plus} ) + 1 )}{2} = \frac{n}{2} + \frac{1}{2} {\sum }_{i = 1}^{n} sgn ( {v}_{os , plus} ) & ( 6 ) \\ {Total}_{- 1 , plus} = - {\sum }_{i = 1}^{n} \frac{( sgn ( {v}_{os , plus} ) - 1 )}{2} = \frac{n}{2} - \frac{1}{2} {\sum }_{i = 1}^{n} sgn ( {v}_{os , plus} ) . & ( 7 )\end{matrix}$$

Similarly, when a negative offset, −v_{offset}, is applied to the comparator reference, v_{ref}, the comparator output becomes:

v_{os,minus}=vᵢ|ₛ−|v_{ref}−v_{offset}|=|vᵢ|ₛ−v_{ref}+v_{offset} (8)

if v_{ref-v}_{offset}≧0, and the statistical distribution becomes:

$$g ( {v}_{os , minus} ) = \frac{1}{σ \sqrt{2 π}} {e}^{\frac{{( {v}_{os , minus} - {v}_{offset} - μ )}^{2}}{2 {σ}^{2}}} . \qquad ( 9 )$$

If we let sgn(v_{os,minus})=1 when v_{os,minus}≧0 and let sg(v_{os,minus})=−1 when v_{os,minus}<0, then for n samples, we have:

$$\begin{matrix}{Total}_{1 , minus} = {\sum }_{i = 1}^{n} \frac{( sgn ( {v}_{os , minus} ) + 1 )}{2} = \frac{n}{2} + \frac{1}{2} {\sum }_{i = 1}^{n} sgn ( {v}_{os , ( minus )} ) & ( 10 ) \\ {Total}_{- 1 , minus} = - {\sum }_{i = 1}^{n} \frac{( sgn ( {v}_{os , minus} ) - 1 )}{2} = \frac{n}{2} - \frac{1}{2} {\sum }_{i = 1}^{n} sgn ( {v}_{os , minus} ) . & ( 11 )\end{matrix}$$

Using the Gaussian distribution derived in Equation (5) for v_{os,minus}, we get:

$$\begin{matrix}\frac{{Total}_{1 , plus}}{n} = p ( {v}_{os , plus} \geq 0 ) = \frac{1}{σ \sqrt{2 π}} {\int }_{0}^{∞} {e}^{\frac{{( {v}_{os , plus} - ( μ - {v}_{offset} ) )}^{2}}{2 {σ}^{2}}} d {v}_{os , plus} . \\ Replacing \frac{{v}_{os , plus} - ( μ - {v}_{offset} )}{σ \sqrt{2}} by y , we get \text{:} & ( 12 ) \\ \frac{{Total}_{1 , plus}}{n} = \frac{1}{\sqrt{π}} {\int }_{\frac{( {v}_{offset} - μ )}{σ \sqrt{2}}}^{∞} {e}^{- {y}^{2}} d y = \frac{1}{2} erfc ( \frac{{v}_{offset} - μ}{σ \sqrt{2}} ) . & ( 13 )\end{matrix}$$

Similarly, using the Gaussian distribution derived in Equation (9) for v_{os,minus}, we get:

$$\begin{matrix}\frac{{Total}_{- 1 , minus}}{n} = p ( {v}_{os , minus} < 0 ) = \frac{1}{σ \sqrt{2 π}} {\int }_{- ∞}^{0} {e}^{\frac{{( {v}_{os , minus} - ( μ + {v}_{offset} ) )}^{2}}{ }} d {v}_{os , minus} . \\ Replacing \frac{{v}_{os , plus} - ( μ + {v}_{offset} )}{σ \sqrt{2}} by z , we get \text{:} & ( 14 ) \\ \frac{{Total}_{- 1 , minus}}{n} = \frac{1}{\sqrt{π}} {\int }_{- ∞}^{\frac{( {v}_{offset} + μ )}{σ \sqrt{2}}} {e}^{- {z}^{2}} d z = \frac{1}{\sqrt{π}} {\int }_{\frac{( {v}_{offset} + μ )}{σ \sqrt{2}}}^{∞} {e}^{- {z}^{2}} d z = \frac{1}{2} erfc ( \frac{{v}_{offset} + μ}{σ \sqrt{2}} ) . & ( 15 )\end{matrix}$$

Re-arranging Equation (13) and Equation (15), we get:

$$\begin{matrix}{v}_{offset} - μ = σ \sqrt{2} {erfc}^{- 1} ( 2 \frac{{Total}_{1 , plus}}{n} ) & ( 16 ) \\ {v}_{offset} + μ = σ \sqrt{2} {erfc}^{- 1} ( 2 \frac{{Total}_{- 1 , minus}}{n} ) . & ( 17 )\end{matrix}$$

The following equations isolate μ and σ:

$$\begin{matrix}μ = \frac{σ}{\sqrt{2}} ( {erfc}^{- 1} ( 2 \frac{{Total}_{- 1 , minus}}{n} ) - {erfc}^{- 1} ( 2 \frac{{Total}_{1 , plus}}{n} ) ) & ( 18 ) \\ σ = \frac{\sqrt{2} {v}_{offset}}{{erfc}^{- 1} ( 2 \frac{{Total}_{1 , plus}}{n} + {erfc}^{- 1} ( 2 \frac{{Total}_{- 1 , minus}}{n} ) )} . & ( 19 )\end{matrix}$$

Finally, the SNR can be estimated using

$$\begin{matrix}SNR = \frac{{v}_{ref}}{σ} & ( 20 ) \\ {SNR}_{dB} = 20 log ( \frac{{v}_{ref}}{σ} ) . & ( 21 )\end{matrix}$$

As noted above, SNR calculations such as those illustrated in Equations (1) to (21), and similarly BER calculations, need not necessarily be performed where it is only desired to confirm or ensure that SNR or BER is within an acceptable limit. In this case, the total tail counts can simply be compared with an appropriate threshold that is related to the SNR/BER limit.

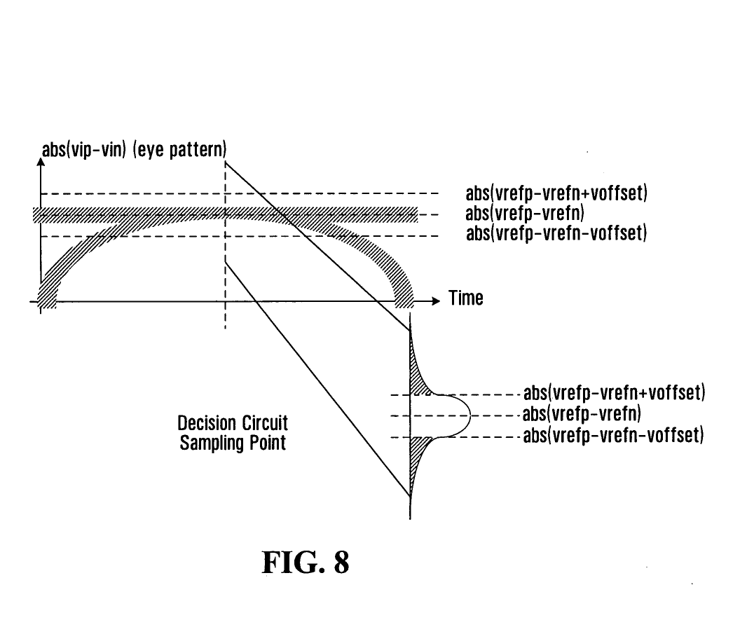

SNR/BER monitor functions could be provided in an apparatus such as shown in FIG. 9, which is a block diagram of an error monitor that incorporates a signal comparison apparatus of an embodiment of the invention. In the monitor 50, an offset element 52 is operatively coupled to a signal magnitude comparator 54. A decision circuit 55 is operatively coupled to the signal magnitude comparator 54, and an accumulator 56 is operatively coupled to the decision circuit and to a timer 58. The timer 58 is also operatively coupled to the offset element 52

The offset element 52 may be implemented as an adder or similar component for adjusting the reference signal, vrefp-vrefn, by an offset, voffset. The signal magnitude comparator 54 may have a structure as described above, for example, and also be used as an error comparator in an adaptive equalization system. The decision circuit 55 may similarly have substantially the same structure as a decision circuit of an adaptive equalization system, and actually be part of both an SNR/BER monitor and an equalization system. The accumulator 56 accumulates the “tail” counts described above during time periods set by the timer 58. The timer 58 may be a programmable timer to allow for adjustment of the tail count interrogation time period. The operative coupling between the timer 58 and the offset element 52 enables the timer to change the polarity of the offset voltage applied to the reference signal of the magnitude comparator 54.

Embodiments of an SNR/BER monitor may differ from the specific example shown in FIG. 9. For instance, respective accumulators may be provided for the positive and negative offset tail counts. Other variations may also be or become apparent to those skilled in the art.

The specific implementation of each component shown in FIG. 9 may also vary. For example, the apparatus 50 could be implemented using digital components, analog components, or a combination of digital and analog components. The accumulator 56 could be implemented in digital form as a counter or in analog form as an analog integrator for instance.

Operation of the apparatus 50 will be apparent from the foregoing description of SNR/BER monitoring functions.

The signal comparison techniques disclosed herein may, as shown in FIG. 9, allow only one comparator device to be used to simultaneously compare an eye pattern with high and low reference values, where the “low” reference is the inverse of the “high” reference for instance. Previously proposed schemes use two comparators to compare the eye pattern to the two reference values. This comparator saving can translate into simplified circuit implementations and lower power consumption, especially at high data rates, illustratively above 1 Gb/s.

Moreover, if a signal monitor is intended to be used in conjunction with an adaptive equalization system, an error comparator from the equalization system can be reused in performing signal monitoring functions for equalizer outputs. That is, an equalizer adaptation algorithm can be periodically frozen or stopped, and the same error comparator can the be used for signal monitoring. Although some additional components such as an accumulator and a timer may be provided for signal monitoring, overall complexity and power consumption may be reduced since equalization and signal monitoring do not require separate comparators.

What has been described is merely illustrative of the application of principles of embodiments of the invention. Other arrangements and methods can be implemented by those skilled in the art without departing from the scope of the present invention.

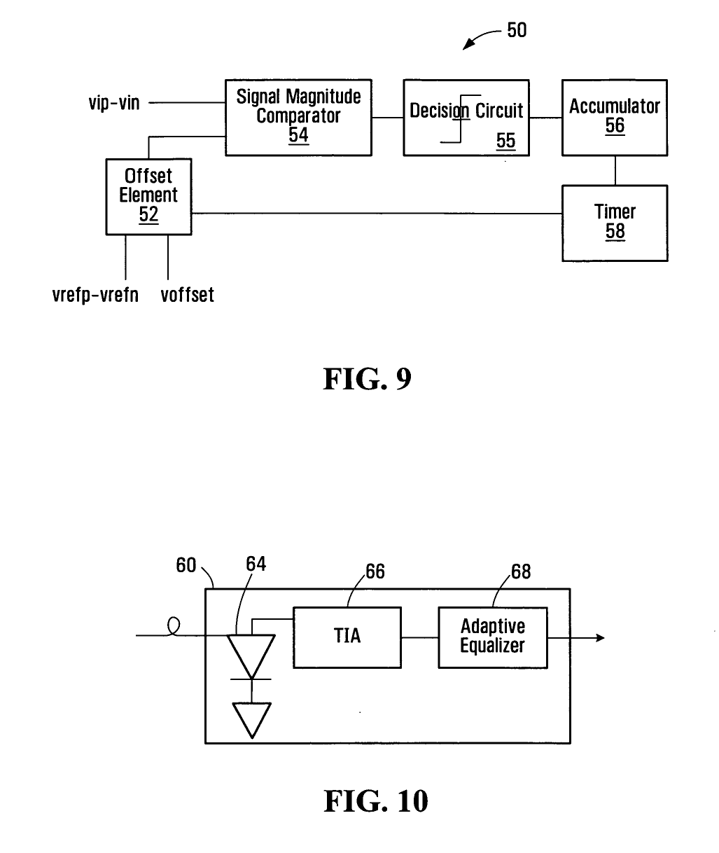

For example, devices in which embodiments of the invention are implemented may be incorporated into further devices or systems. FIG. 10 is a block diagram of an optical module incorporating a signal comparison apparatus according to an embodiment of the invention. In FIG. 10, an optical module 60 receives signals on an optical link. A photodiode 64 detects the received optical signals, which are further processed by a transimpedance amplifier (TIA) 66 and an adaptive equalizer 68. As described above, the adaptive equalizer 68 may incorporate a signal magnitude comparator as disclosed herein.

The optical module 60 represents one further example of a possible application of embodiments of the invention. Other applications are also contemplated, and may be or become apparent to those skilled in the art.

We claim:

1. An apparatus comprising:
a first input circuit operable to receive a differential input signal and to provide a first output signal based on a magnitude of the differential input signal; and
a second input circuit operatively coupled to the first input circuit, the second input circuit being operable to receive a second input signal and to provide a second output signal based on a magnitude of the second input signal,
the first output signal and the second output signal comprising a differential output signal that is indicative of a difference between the magnitude of the first differential input signal and the magnitude of the second input signal.

2. The apparatus of claim 1, wherein the first input circuit comprises:
a pair of controllable switch elements, each controllable switch element being operatively coupled between supply rails and operable to receive as a control input a respective one of a pair of input signals comprising the first differential input signal, and to provide, under control of its control input, a respective connection between the supply rails.

3. The apparatus of claim 2, wherein the first input circuit further comprises a load operatively coupled between the pair of controllable switch elements and one of the supply rails.

4. The apparatus of claim 2, further comprising:
a connection circuit operatively coupling the first input circuit to the second input circuit, the connection circuit comprising a current source operatively coupling both the first input circuit and the second input circuit to one of the supply rails.

5. The apparatus of claim 3, further comprising:
a connection circuit operatively coupling the first input circuit to the second input circuit, the connection circuit comprising a current source operatively coupling both the first input circuit and the second input circuit to the other of the supply rails.

6. The apparatus of claim 1, wherein the second input circuit comprises:
a controllable switch circuit operatively coupled between supply rails and operable to receive as a control input the second input signal, and to provide, under control of the second input signal, a connection between the supply rails.

7. The apparatus of claim 6, wherein the second input signal comprises a differential input signal, and wherein the controllable switch circuit comprises:
a pair of controllable switch elements, each controllable switch element being operatively coupled to the supply rails and operable to receive as a control input a respective one of a pair of input signals comprising the second differential input signal, and to provide, under control of its control input, a respective connection between the supply rails.

8. The apparatus of claim 6, wherein the second input circuit further comprises a load operatively coupled between the controllable switch circuit and one of the supply rails.

9. The apparatus of claim 6, further comprising:
a connection circuit operatively coupling the first input circuit to the second input circuit, the connection circuit comprising a current source operatively coupling both the first input circuit and the second input circuit to one of the supply rails.

10. The apparatus of claim 8, further comprising:
a connection circuit operatively coupling the first input circuit to the second input circuit, the connection circuit comprising a current source operatively coupling both the first input circuit and the second input circuit to the other of the supply rails.

11. The apparatus of claim 2, wherein the second input circuit comprises:
a controllable switch circuit operatively coupled to the supply rails and operable to receive as a control input the second input signal, and to provide, under control of the second input signal, a second connection between the supply rails.

12. The apparatus of claim 11, wherein the first input circuit further comprises a first load operatively coupled between the pair of controllable switch elements and one of the supply rails, and wherein the second input circuit further comprises a second load operatively coupled between the controllable switch circuit and the one of the supply rails.

13. The apparatus of claim 11, further comprising:
a connection circuit operatively coupling the first input circuit to the second input circuit, the connection circuit comprising a current source operatively coupling both the first input circuit and the second input circuit to one of the supply rails.

14. The apparatus of claim 12, further comprising:
a connection circuit operatively coupling the first input circuit to the second input circuit, the connection circuit comprising a current source operatively coupling both the first input circuit and the second input circuit to the other of the supply rails.

15. The apparatus of claim 1, wherein the first input circuit and the second input circuit comprise controllable switch elements.

16. A signal equalization system comprising:
an equalizer operable to receive a signal and to equalize the received signal in accordance with equalization coefficients;
an error comparator operatively coupled to the equalizer, the error comparator comprising the apparatus of claim 1 and being operable to receive an equalized signal from the equalizer and a reference signal as the first differential input signal and the second input signal, respectively;
respective decision circuits operatively coupled to the equalizer and to the error comparator; and
an adaptation module operatively coupled to the decision circuits and to the equalizer, the adaptation module being operable to determine the equalizer coefficients based on outputs of the decision circuits.

17. The equalization system of claim 16, further comprising:
an offset element operatively coupled to the error comparator and operable to adjust the reference signal by an offset amount and to provide the adjusted reference signal to the error comparator as the second input signal; and
an accumulator operatively coupled to the error comparator decision circuit and operable to accumulate a number of times at which the differential output signal indicates that a magnitude of the equalized signal is above a magnitude of the adjusted reference signal when the reference signal is increased by the offset amount, and to accumulate a number of times at which the differential output signal indicates that a magnitude of the equalized signal is below a magnitude of the adjusted reference signal when the reference signal is decreased by the offset amount.

18. A signal monitor comprising:
the apparatus of claim 1;
an offset element operatively coupled to the apparatus and operable to adjust a reference signal by an offset amount and to provide the adjusted reference signal to the error comparator as the second input signal;
a decision circuit operatively coupled to the apparatus to receive the differential output signal; and
an accumulator operatively coupled to the apparatus and operable to accumulate a number of times at which the differential output signal indicates that a magnitude of the first differential input signal is above a magnitude of the adjusted reference signal when the reference signal is increased by the offset amount, and to accumulate a number of times at which the differential output signal indicates that a magnitude of the first differential input signal is below a magnitude of the adjusted reference signal when the reference signal is decreased by the offset amount.

19. A method comprising:
receiving a first differential input signal and a second input signal;
converting the first differential input signal and the second input signal into respective output signals based on magnitudes of the first differential input signal and the second input signal; and
providing a differential output signal comprising the respective output signals, the differential output signal being indicative of a difference between the magnitude of the first differential input signal and the magnitude of the second input signal.

20. An apparatus comprising:
a pair of input circuits operable to respectively receive a first differential input signal and a second input signal, and to provide respective output signals based on a magnitude of the first differential input signal and a magnitude of the second input signal; and
a connection circuit operatively coupling the pair of input circuits together, such that the respective output signals comprise a differential output signal that is indicative of a difference between the magnitude of the first differential input signal and the magnitude of the second input signal.
